(19) United States
(12) Patent Application Publication
(10) Pub. No.: US 2008/0288906 A1
(43) Pub. Date: Nov. 20, 2008

(54) Integrated system on module

(76) Inventors: Troy D. Kopischke, Hamel, MN (US); John J. Michael, St. Michael, MN (US); Kurt T. Larson, Plymouth, MN (US); Gary F. Soebbing, Minnetonka, MN (US); Hans A. Rempel, Vancouver, WA (US); Richard A. Kinnunen, Maple Grove, MN (US)

Correspondence Address: MERCHANT & GOULD PC, P.O. BOX 2903, MINNEAPOLIS, MN, 55402-0903, US

(21) Appl. No.: 11/787,196

(22) Filed: Apr. 13, 2007

(51) Int. Cl. G06F 17/50; H01L 25/00

(52) U.S. Cl. 716/9; 326/41

(57) ABSTRACT

An electronic product includes a circuit board, an integrated system on module, and an application-specific module. The integrated system on module and the application-specific module are integrated with the circuit board. A method of forming the circuit board is disclosed, as well as a method of forming the electronic product.

### TECHNICAL FIELD

The present disclosure relates to electronics, and more particularly to electronic products involving a circuit board.

### BACKGROUND

The development of a new electronic product often requires a significant investment of time and resources. The process of researching, designing, prototyping, manufacturing, and testing often requires years to complete at a substantial cost to the new product developer. In addition, certain features of the product may be beyond the capabilities of the product developer. As a result, the product developer may need to hire new employees or outside consultants having the appropriate expertise to develop those features of the product. Even if the product developer decides to hire a new employee or outside consultant, it is sometimes difficult to quickly locate a person having the appropriate skill or expertise to develop the needed features.

System on module technology has been developed to respond to this need. With system on module technology, the product developer no longer has to custom engineer the entire new product. Rather, the product developer can select from among various systems on modules that have already been designed to perform the necessary functions.

One type of system on module is entirely contained on its own circuit board. A product developer that desires to use the system on module within a new product, designs the new product to interface with the system on module. For example, the product developer custom designs a second circuit board containing the features or components desired for the new product. The second circuit board is designed having mechanical connectors that are capable of mating with connectors located on the system on module circuit board. In this way, a new product can be developed in less time and with less expense than custom engineering the entire new product.

Despite these benefits, however, it has been found that systems on modules are not without problems. For example, the mechanical connections between the system on module board and the second circuit board are prone to fail over time. These and other problems are addressed by various embodiments according to the present disclosure.

### SUMMARY

In general terms, and by non-limiting example, the present disclosure is directed to an electronic product comprising an integrated system on module, an application-specific module, and a circuit board. The integrated system on module and the application-specific module are integrated with the circuit board.

Another aspect is an electronic product including a circuit board, an integrated system on module, an application-specific module, and a common interface. The integrated system on module includes a plurality of integrated system on module components arranged within a bounded region of the circuit board. The integrated system on module components are further arranged to perform a desired system function. The application-specific module includes a plurality of application-specific module components arranged outside of the bounded region of the circuit board. The application-specific module components are further arranged to perform an application-specific function. The common interface is defined adjacent the bounded region, wherein the integrated system on module and the application-specific module are connected at the common interface, and wherein the integrated system on module and the application-specific module are integrated with the circuit board.

Another aspect is a method of developing an electronic product. The method includes defining a design for an integrated system on module including a common interface, the integrated system on module design being designed to be constructed within a bounded region of a circuit board and being designed to include a plurality of components arranged to perform a system function; and providing the integrated system on module design to a product developer to enable the product developer to design an application-specific module comprising a plurality of components arranged to perform an application-specific function, wherein the application-specific module connects with the integrated system on module at the common interface when the application-specific module and the integrated system on module are integrated with a single circuit board.

A further aspect is a method of forming a circuit board. The method includes developing a first integrated system on module design based on a first plurality of integrated system on module components, wherein the first integrated system on module design defines a first integrated system on module designed to perform a system function; developing a second integrated system on module design based on a second plurality of integrated system on module components, wherein the second integrated system on module design defines a second integrated system on module designed to perform a second system function; developing an application-specific module design based on a plurality of application-specific module components, wherein the application-specific module design defines an application-specific module designed to perform an application-specific function; and constructing a circuit board comprising a bounded region and a common interface adjacent the bounded region, wherein the application-specific module is formed in the circuit board outside the bounded region and connects with the common interface, and wherein the common interface is connected to and enables the circuit board to be interchangeably constructed with either the first integrated system on module or the second integrated system on module.

Another aspect is a method of forming a circuit board. The method includes developing an integrated system on module design based on a plurality of integrated system on module components, wherein the integrated system on module design defines an integrated system on module designed to perform a system function; developing a first application-specific module design based on a second plurality of application-specific module components, wherein the first application-specific module design defines a first application-specific module designed to perform a first application-specific function; developing a second application-specific module design based on a second plurality of application-specific module components, wherein the second application-specific module design defines a second application-specific module designed to perform a second system function; and constructing a circuit board comprising a bounded region and a common interface adjacent the bounded region, wherein the integrated system on module is formed in the circuit board within the bounded region and connects with the common interface, and wherein the common interface is connected to and enables the circuit board to be interchangeably constructed with either the first application-specific module or the second application-specific module.

### BRIEF DESCRIPTION OF THE DRAWINGS

FIG. 1 is a top view of an example electronic product including a circuit board, an integrated system on module, an application-specific module, and a common interface.

FIG. 2 is a block diagram of an example of the integrated system on module of FIG. 1.

FIG. 3 is a block diagram of an example of the application-specific module of FIG. 1.

FIG. 4 is a flow chart illustrating an example method of making the electronic product shown in FIG. 1.

FIG. 5 is a flow chart illustrating an example method of forming the circuit board shown in FIG. 1.

FIG. 6 is a flow chart illustrating another example method of forming the circuit board shown in FIG. 1.

FIG. 7 is a block diagram further illustrating the designing and merging of an integrated system on module design and an application-specific module design.

### DETAILED DESCRIPTION

Various embodiments will be described in detail with reference to the drawings, wherein like reference numerals represent like parts and assemblies throughout the several views. Reference to various embodiments does not limit the scope of the claims attached hereto. Additionally, any examples set forth in this specification are not intended to be limiting and merely set forth some of the many possible embodiments for the appended claims.

In general terms, and by non-limiting example, the present disclosure is directed to an electronic product comprising an integrated system on module, an application-specific module, and a circuit board. The integrated system on module and the application-specific module are integrated with the circuit board.

Some embodiments of an electronic product according to the present disclosure are more robust than conventional systems. For example, by integrating the integrated system on module and application-specific module onto the same circuit board, the standard mechanical connections required to connect the integrated system on module with a second circuit board are eliminated. This is beneficial because mechanical connections are prone to failure over time. Other benefits and features of certain embodiments are also realized, as described herein.

Another benefit realized by some embodiments is that the electronic product can be formed having a reduced profile. The reduced profile is a result of integrating all components with the same circuit board, rather than requiring that another circuit board be stacked on top of a base circuit board. For example, the profile can be reduced by at least the thickness of the second circuit board and the height of the components on the second circuit board.

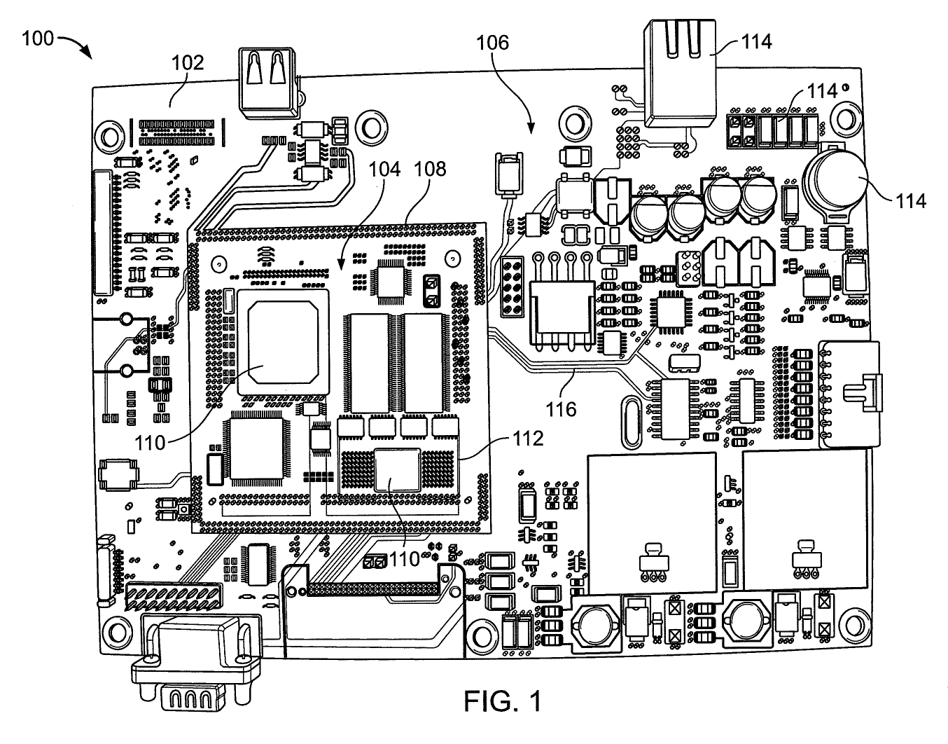

FIG. 1 is a top view of an example electronic product 100. Electronic product 100 includes circuit board 102, integrated system on module 104, application-specific module 106, and common interface 108. Integrated system on module 104 includes components 110 and traces 112. Application-specific module 106 includes components 114 and traces 116.

In some embodiments, circuit board 102 is a printed circuit board. Circuit board 102 is formed of one or more layers of insulating material, sometimes referred to as a substrate. A multi-layer circuit board 102 can be formed by fastening together multiple layers of insulating material, such as with an adhesive. Circuit board 102 provides mechanical support to integrated system on module 104 and application-specific module 106, including components 110 and 114 and traces 112 and 116.

In general terms, integrated system on module 104 is a distinct unit of hardware that is specially configured to perform a function or set of functions for an electronic product 100. In one embodiment, integrated system on module 104 is configured to provide a system function, such one or more of the various functions described herein. In some embodiments, system on module 104 is configured to perform at least two system functions. Integrated system on module 104 is integrated with circuit board 102. In some embodiments, integrated system on module 104 is designed and configured independent of application-specific module 106. In other words, integrated system on module 104 is designed and configured to perform a function or set of functions independent of any particular application. Rather, integrated system on module 104 is a functional block that can be incorporated into a variety of different products.

Integrated system on module 104 includes one or more components 110 and traces 112. Components 110 and traces 112 are formed on or within circuit board 102. In one embodiment, components 110 include thru-hole components, surface mount components, mechanical components, or any other desired components. Thru-hole components include one or more leads which are inserted through vias formed in circuit board 102. The leads are then soldered to electrical contacts formed on circuit board 102 to fasten and electrically connect the thru-hole component to circuit board 102. Surface mount components are fastened and electrically connected to circuit board 102 by soldering the surface mount components to electrical contacts located on a surface of circuit board 102. Mechanical components may also be fastened to circuit board 102 using fasteners such as, adhesive, screws, nuts and bolts, nails, hook and loop fasteners, rivets, adhesive tape, or any other suitable faster.

In some embodiments, electrical traces 112 are also formed on or within circuit board 102 to provide electrical connections between components 110 and 114 and to common interface 108. Traces 112 can be formed on the outer surfaces of circuit board 102 or on any layer within circuit board 102. One method of forming traces 112 is to deposit a layer of electrically conductive material, such as copper on the substrate. A temporary mask is then applied over the desired trace locations. The unmasked conductive material is removed by a process such as etching. The temporary mask protects traces 112 during the etching process. After the undesired conductive material has been removed, the temporary mask is removed revealing traces 112. Other known methods of forming traces may also be used, including electroplating, milling, photoengraving, and the like. In another embodiment, electric wires are used instead of traces 112.

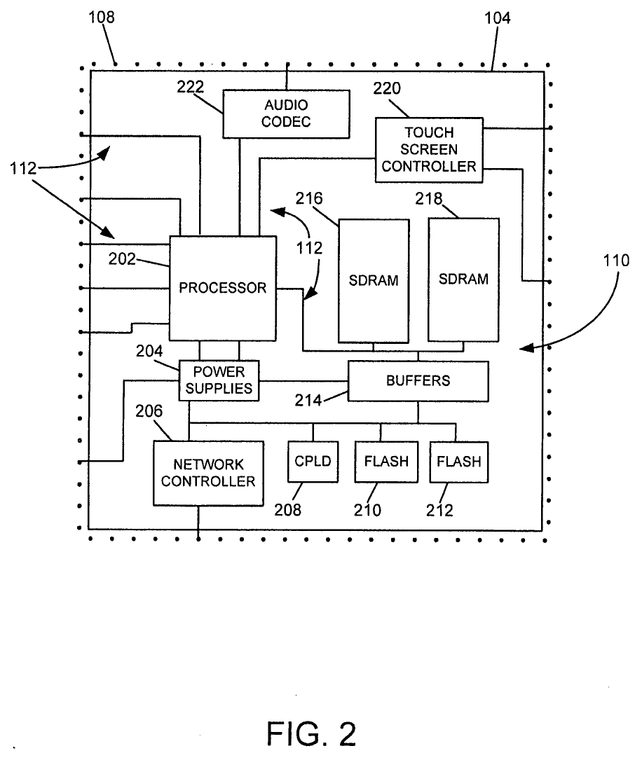

In one embodiment, and by non-limiting example, integrated system on module components 110 include a processor, memory, and a communication system capable of interfacing between integrated system on module 104 and application-specific module 106. Integrated system on module 104 is illustrated and described in more detail with reference to FIG. 2.

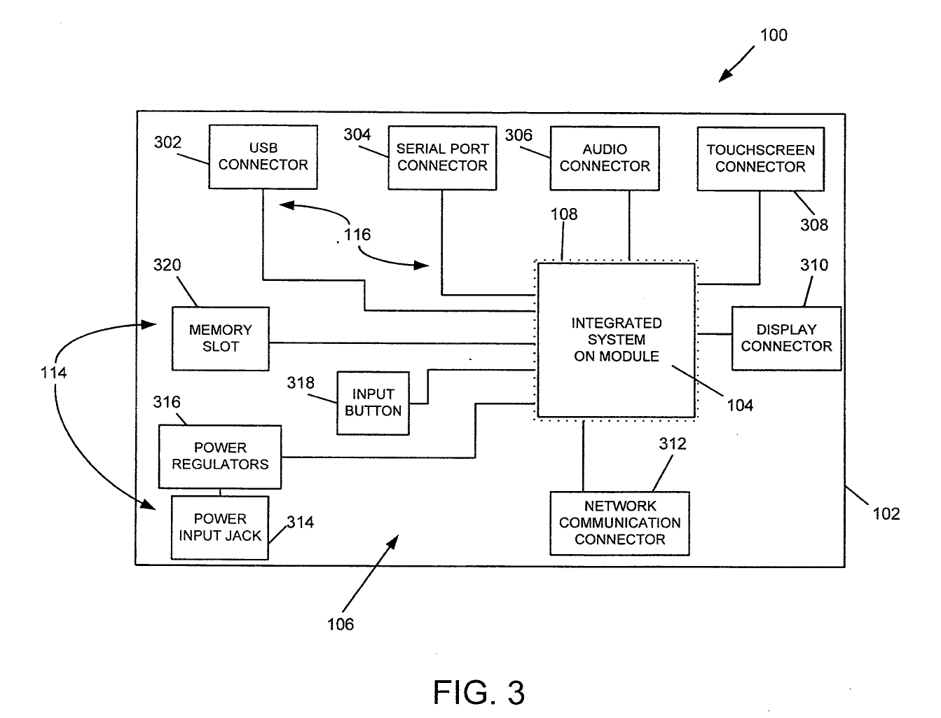

In general terms, application-specific module 106 is a specially designed and configured set of components that interact with integrated system on module 104 to perform the specific functions of electronic product 100. In some possible embodiments, application-specific module 106 is custom designed for the particular application. Application-specific module 106 includes components 114 and traces 116. The selection and arrangement of components 114 depends on the features and functionality that is desired of electronic product 100. For example, if it is desired that electronic product 100 interface with a touch screen display, one of components 114 will likely be a touch screen display connector, capable of interfacing with the touch screen. Traces 116 are formed on or within circuit board 102 to connect between components 114 and to connect components 114 with common interface 108. Traces 116 may be formed on or within circuit board 102 in the same manner as traces 112 described herein. Application-specific module 106 is illustrated and described in more detail with reference to FIG. 3.

In the illustrated embodiment, integrated system on module 104 is surrounded on board 102 by application-specific module 106. Other possible embodiments include other configurations. For example, in another embodiment integrated system on module 104 and application-specific module 106 are located side-by-side on board 102. Various other configurations are also possible.

Common interface 108 is located at the intersection between integrated system on module 104 and application-specific module 106. In one embodiment, and by non-limiting example, common interface 108 includes a set of thru-holes formed in circuit board 102. Traces 112 and traces 116 are each designed to connect with common interface 108. In another embodiment, common interface 108 is a footprint that defines the electrical connections that are possible between integrated system on module 104 and application-specific module 106. For example, the footprint identifies the location of a set of electrical contact points. In another embodiment, the purpose or function of each contact point is identified for common interface 108. In one exemplary embodiment, a contact point is identified as an audio input point. This point can then be used to provide an audio input from application-specific module 106 to integrated system on module 104. In another embodiment, common interface 108 also identifies a region of circuit board space into which the integrated system on module will be located. This region of space may also be referred to as the footprint of the integrated system on module. In another embodiment, the footprint of the integrated system on module also includes the footprint of the common interface.

One of the benefits of common interface 108 is that it enables integrated system on module 104 and application-specific module 106 to be designed independent of each other, so long as each design includes the same common interface 108. After the design is complete, the designs of the integrated system on module 104 and application-specific module 106 can be merged onto a single circuit board 102.

By integrating system on module 104 with the same board as application-specific module 106, no mechanical connections are required to connect integrated system on module 104 and application-specific module 106. This improves the quality and reliability of electronic product 100, because mechanical connections are a common point of failure, resulting from vibration, corrosion, and the like. In some embodiments, electronic product 100 is less expensive to manufacture because only a single circuit board 102 is required, and also because mechanical connectors are not required to connect integrated system on module 104 with application-specific module 106. Furthermore, some embodiments benefit from a reduced profile as described herein.

FIG. 2 is a block diagram of an example integrated system on module 104 and common interface 108. Integrated system on module 104 includes components 110 and traces 112. The particular components of an embodiment of integrated system on module 104 will vary depending on the features and functionality desired. Therefore, the components illustrated in FIG. 2 illustrates only one possible embodiment, and no particular components illustrated are required by all embodiments. In the illustrated example, components 110 include processor 202, power supplies 204, network controller 206, complex programmable logic device 208, flash memory 210 and 212, buffers 214, SDRAM 216 and 218, touch screen controller 220, and audio codec 222. In some embodiments, integrated system on module 104 includes a plurality of components, the plurality of components being at least 2 components. In another embodiment, integrated system on module 104 includes at least three components. For example, integrated system on module 104 includes a processing device, a memory component, and an interface component, such as a communication component capable of communicating data between integrated system on module 104 and application-specific module 106.

One example of processor 202 is the PXA270 32-bit microprocessor manufactured by Marvell Semiconductor, Inc. of Santa Clara, Calif. Alternatively, various other processing devices may also be used including other microprocessors, central processing units (“CPUs), microcontrollers, programmable logic devices, field programmable gate arrays, digital signal processing (“DSP”) devices, and the like. Processing devices may be of any general variety such as reduced instruction set computing (RISC) devices, complex instruction set computing devices (“CISC”), or specially designed processing devices such as an application-specific integrated circuit (“ASIC”) device.

Power supplies 204 supply power to components 110 of integrated system on module 104. In one embodiment, power supplies 204 receive power through common interface 108, and filters and/or transforms that power into an appropriate form. For example, power supplies 204 can provide various voltage outputs such as 1.5V, 3V, and 5V outputs. Some of traces 112 are used to deliver the power throughout integrated system on module 104. In an alternate embodiment, power supplies 204 include one or more batteries. The power supplies can be of any appropriate variety such as, but not limited to, linear-type regulators or switching-type regulators.

Network controller 206 controls network communication between integrated system on module 104 and external components, such as application-specific module components or components external to electronic product 100. One example of network controller 206 is an Ethernet controller. A more specific example is a 10/100 BASE-T Ethernet controller, such as LAN 91C111, manufactured by SMSC® located in Hauppauge, N.Y.

Complex programmable logic device (“CPLD”) 208 is an example of another programmable device used in some embodiments of integrated system on module 104. CPLD 208 is a programmable device capable of performing a variety of functions. Other programmable logic devices may also be used. Alternatively, or in addition to CPLD 208, a field programmable gate array (“FPGA”) is included.

Some embodiments of integrated system on module 104 include memory. In the illustrated embodiment, integrated system on module 104 includes flash memory 210 and 212, buffers 214, and synchronous dynamic access memory (“SDRAM”) 216 and 218. Alternative forms of memory included in some embodiments of integrated system on module 104 include random access memory (“RAM”) including all varieties of static and dynamic memory, read only memory (“ROM”), and other known forms of digital storage.

In some embodiments it is desirable for electronic product 100 to interface with a display or touch screen. In the illustrated embodiment, touch screen controller 220 controls the output of display data and receives input from the touch screen. One example of a touch screen controller is the UCB1400 manufactured by NXP® located in Eindhoven, The Netherlands.

It is also sometimes desirable to have audio input or output capabilities. In such embodiments, audio codec 222 is provided. One example of an audio codec is the UCB1400 manufactured by NXP®, which has both audio codec and touch screen capabilities (as discussed above).

In other embodiments, integrated system on module 104 is capable of performing a wide variety of functions with a wide variety of components 110. No particular functions or components are required by all embodiments. Some examples include, but are not limited to, implementing a user interface controller, control system, motor controller, base station, signal repeater, computing engine, bus arbiter, a display panel driver, a wireless receiver, a wireless transmitter, and a wireless transceiver. Other examples include, but are not limited to operating as an interface controller for Universal Asynchronous Receiver/Transmitter (“UART”), Universal Serial Bus (“USB”), Peripheral Component Interconnect (“PCI”), PCI Express (“PCIE”), a host bus, Ethernet, Gigabit Ethernet, Serial Peripheral Interface (“SPI”), and Inter-Integrated Circuit (“I²C”). Further examples include operating as an Audio Codec '97 (“AC97”) controller, liquid crystal display controller (“LCD”), analog to digital converter (“ADC”) controller, and digital to analog converter (“DAC”) controller. In some possible embodiments, integrated system on module 104 is or includes an embedded system. In another possible embodiment, integrated system on module 104 is a memory storage device such as a Flash Drive or a digital memory storage module including all supporting circuitry for use in a specified system. In another possible embodiment, integrated system on module 104 is a RAM circuit, including RAM and supporting circuitry, such as bus circuitry logic, serial or parallel busing, and address decoding circuitry.

Integrated system on module components 110 also include an antenna in some possible embodiments. The antenna is connected to a receiver or a transmitter capable of sending or receiving signals using electromagnetic waves, such as radio waves to enable integrated system on module 110 to communicate with components outside of integrated system on module 110. A wide variety of antennas can be used including a dipole antenna. In another embodiment, an antenna is embedded on or within the circuit board, such as circuit board 102. For example, one or more of traces 112 can be designed to have a shape and configuration to receive or transmit radio waves. In another example, the antenna is formed by a process separate from the formation of traces 112, by etching copper plating on one or more layers of the circuit board.

Some embodiments of integrated system on module 104 are completely contained within a bounded region of space on circuit board 102. In the illustrated embodiment, integrated system on module 104 is contained within a generally square region of space. In other embodiments, bound regions are designed having other shapes including rectangular, circular, elliptical, or triangular. In addition, regions of space having more complex shapes can also be formed. In some embodiments, common interface 108 completely or partially surrounds the periphery of the region of space.

Common interface 108 is the interface through which integrated system on module 104 is able to connect to application-specific module 106. Therefore, some of traces 112 are routed from components 110 to common interface 108 to provide electrically conductive passageways for communicating with application-specific module 106. As described herein, one example of common interface 108 is a pattern of vias formed in circuit board 102. Vias are typically formed by drilling holes in one or more layers of circuit board 102 and then coating the holes with an electrically conductive material, such as copper. In another embodiment, common interface 108 is a set of contact points located on or within circuit board 102, such that holes are not required in all embodiments of circuit board 102 to form common interface 108. In some embodiments, common interface 108 is defined at the periphery of the integrated system on module to surround or partially surround the integrated system on module. For example, FIG. 1 illustrates an embodiment in which common interface 108 partially surrounds integrated system on module 104. FIGS. 2-3 illustrate an embodiment in which common interface 108 completely surrounds integrated system on module 104.

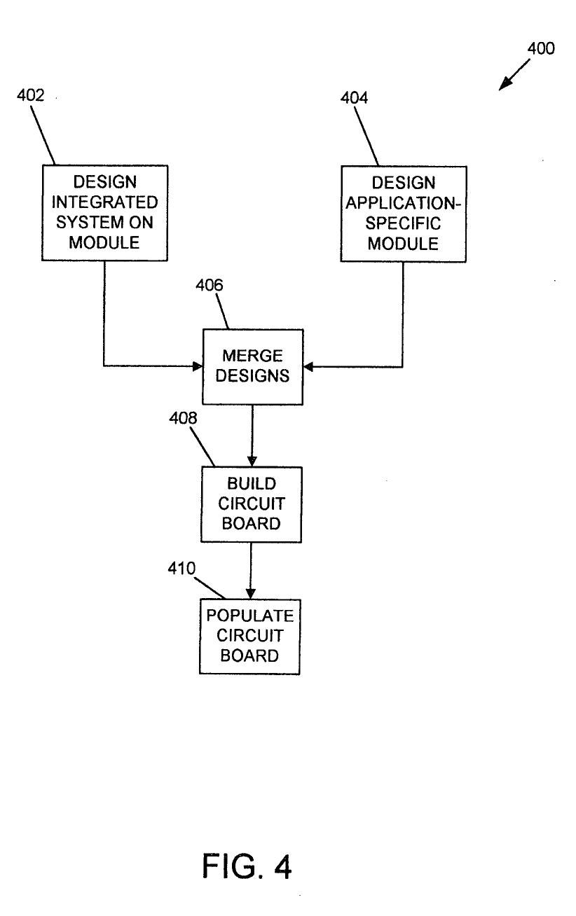

As described in more detail herein with reference to FIGS. 4-7, common interface 108 provides benefits in some embodiments when modifications are needed to the design of an electronic product 100. Rather than requiring that an entire electronic product design be redesigned to incorporate changes to the electronic product, only a portion (a module) of the electronic product is modified. For example, if a change is desired to the integrated system on module, the changes are made to the integrated system on module design, but no changes have to be made to the application-specific module design or the common interface design. In another example, should a change be desired to the application-specific module, the changes are made to the application-specific module design, but no changes have to be made to the integrated system on module design or the common interface. As a result, and increased time to market is realized with decreased development costs.

This benefit is further compounded in some embodiments due to the time and cost savings of not having to re-test a previously-designed and previously-tested module of a circuit board. Some problems experienced by some circuit board designs is coupling between adjacent signal traces, noise problems, ground lift problems, power supply interference problems, and the like. After a circuit board module has been designed, it will sometimes be tested for these and other problems. A benefit of some embodiments is that modules that have already been designed and tested do not have to be redesigned or retested when the other module is modified, because no changes are made to the module or the common interface. For example, if the application-specific module design has already been built, tested, and found to be suitable for the desired functions, the application-specific module design does not have to be retested when one integrated system on module design is swapped with a different integrated system on module design. The same is true if a pre-built and pre-tested integrated system on module design is kept but an application-specific module design is swapped with a different application-specific module design.

FIG. 3 is a block diagram of an example electronic product 100 including integrated system on module 104, application-specific module 106, and common interface 108. Application-specific module 106 includes components 114 and traces 116. The particular components of application-specific module 106 will vary depending on the features and functionality desired, and on the capabilities provided by integrated system on module 104. Therefore, the components illustrated in FIG. 3 illustrate only one possible embodiment, and no particular components illustrated are required by all embodiments. In the illustrated embodiment, components 114 include USB connector 302, serial port connector 304, audio connector 306, touch screen connector 308, display connector 310, network communication connector 312, power input jack 314, power regulators 316, input button 318, and memory slot 320.

In the illustrated example, a variety of connectors are included in application-specific module 106. The connectors are, for example, a receptacle for receiving a communication line. Examples include a universal serial bus (“USB”) connector 302 for receiving a USB cable, a serial port connector 304 for receiving a serial port cable, an audio connector 306 for receiving audio or microphone cables, a touch screen connector 308 for receiving a touch screen cable, a display connector 310 for receiving a display cable, a network communication connector, such as for receiving an Ethernet cable, and a power input jack 314 for receiving a power cable.

In the illustrated example, application-specific module 106 includes power regulators 316. Power regulators 316 are connected to power input jack 314 to regulate power received through power input jack 314. In one example, power regulators 316 regulate input power at 5V and 3.3V. In addition, hot swap protection is included in some embodiments to protect against electrostatic discharge (“ESD”). Power is then distributed, such as through traces, to components of application-specific module 106 and integrated system on module 104.

Input button 318 is shown in the illustrated embodiment of application-specific module 106. In one example, input button 318 is a reset button. When pressed, input button 318 sends a reset signal to integrated system on module 104. Additional input buttons can be included in some embodiments if additional user input capabilities are desired.

Memory slot 320 is also included in the illustrated embodiment of application-specific module 106. One example of memory slot 320 is a compact flash slot for receiving compact flash cards. Other embodiments include other memory storage devices. In one embodiment, one or more traces connecting between memory slot 320 and integrated system on module 104 operate as an extended system bus with integrated system on module 104. In this way, a system bus of integrated system on module 104 can be extended onto application-specific module 106.

In other embodiments, application-specific module 106 is capable of performing a wide variety of functions with a wide variety of components 114. No particular functions or components are required by all embodiments. Some examples include, but are not limited to, interfacing with input devices, displays, Local Interconnect Network (“LIN”) bus, PCI devices, PCI Express devices, and host based devices, power sources (including direct current supplies, alternating current supplies, and batteries). Example input devices include a keypad, keyboard, button, touchpad, mouse, trackball, touch screen and the like. Example display devices include liquid crystal display (“LCDs”), Video Graphics Array (“VGA”) displays, cathode ray tube (“CRT”) displays, and the like. Other examples include light emitting diodes (“LEDs”), sensors (such as magnetic sensors, hall effect sensors, light sensors, temperature sensors, humidity sensors, acceleration sensors, biometric sensors, pressure sensors, and the like), RS-232 ports, RS-485 ports, LCD converters, real time clock devices, radio frequency components including Bluetooth® wireless technology interfaces, 802.11 wireless components, cellular based communication devices, Controller Area Network (“CAN”) components, Personal Communications Services (“PCS”) devices, Global System for Mobile Communications (“GSM”) components, Code Division Multiple Access (“CDMA”) devices, Time Division Multiple Access (“TDMA”) devices, charge controllers, motor actuators, user interface devices, speakers, microphones, optical encoders, Global Positioning System (“GPS”) receivers and transmitters, graphics controllers, set-top box interface, digital and/or analog television components (including for interfacing, encoding, or decoding), encryption devices, memory storage devices, USB host device, OnTheGo® interfaces, USB hub chips, and bridge chips for PCI, host bus, Ethernet, gigabit Ethernet, ADC, DAC, and the like. Examples of memory storage devices include PCMCIA, Secure Digital (SD) cards, miniSD cards, Smart Media, and Multimedia Card (MMC). In some embodiments, application-specific module 106 includes one or more of a processor, a microprocessor, a microcontroller, a CPLD, and a field programmable gate array (“FPGA”).

FIG. 3 also illustrates an embodiment of electronic product 100 from an example product developer's perspective. The product developer who decides to use integrated system on module 104 within a new product does not need to know anything about the design of integrated system on module 104. In one example, all that the product developer needs to know is the footprint of the integrated system on module and what inputs or outputs are available to interact with the application-specific module. In one embodiment the footprint of the integrated system on module includes the dimensions of the integrated system on module and the common interface 108 to which the integrated system on module is designed to interface with. In another embodiment, all that is required is that the product developer is provided with the configuration of the common interface 108. With this information, the product developer can then design application-specific module 106 to interface with integrated system on module 104.

A benefit realized by some embodiments of electronic product 100 is that upgrading, such as to incorporate new advances in technology, is simplified. When integrated system on module 104 is upgraded to include a faster processor, for example, no changes need to be made to the design of application-specific module 106, so long as integrated system on module 104 maintains the same common interface 108. Similarly, when the product developer makes modifications to the design of application-specific module 106, no changes have to be made to the design of integrated system on module 104, provided that the common interface 108 is unchanged. In some embodiments, electronic product 100 itself is not upgradeable, but subsequently manufactured versions of electronic product 100 can be upgraded to incorporate the design changes.

FIG. 4 is a flow chart illustrating an example method 400 of making an electronic product, such as electronic product 100 shown in FIG. 1. Method 400 begins with operations 402 and 404, which can be performed simultaneously or one after the other. Operation 402 involves designing the integrated system on module. During this operation, for example, components are chosen and an electrical schematic is developed. In one embodiment, operation 402 is performed manually, such as through a computer aided drafting (“CAD”) software application. In another embodiment, operation 402 involves automated processes. The board layout and circuit board routing is also defined for the integrated system on module. In a possible embodiment, the resulting design identifies the locations of traces, vias, electrical contacts, and the like, for the integrated system on module. The same process is performed in operation 404, during which the application-specific module is designed. In one embodiment, operation 404 is performed manually, such as through a computer aided drafting software application. In another embodiment, operation 404 involves automated processes. The design of the integrated system on module and the application-specific module can be performed completely independent of each other, if desired, so long as a common interface is defined. In a possible embodiment, the resulting design identifies the locations of traces, vias, electrical contacts, and the like, for the application-specific module.

One of the benefits of some embodiments relates to the split design processes of operations 402 and 404. In one example embodiment, operation 402 is performed by people skilled in the development of the integrated system on module, while operation 404 is performed by people knowledgeable about the features and capabilities desired by the application-specific module, such as the product developer. In this way, the product developer is not required to have any particular knowledge or skill in the development or design of the integrated system on module. In one possible embodiment, the product developer purchases the design of the integrated system on module from those skilled in the development of integrated systems on modules. In such an embodiment, the product developer is not required to hire new employees or skilled consultants to custom engineer a product to perform the features enabled by the integrated system on module.

Once both the integrated system on module and the application-specific module have been designed, the designs are merged into a single design for the electronic product. The designs will merge together if the common interface was adhered to in each design, and if no components or traces were designed outside of the board space allotted to the respective module.

The resulting design for the electronic product is then used in operation 408 to build the circuit board. Building the circuit board involves forming the circuit board having vias, blind vias, traces, electrical contacts, and the like, as defined by the design for the electronic product. The circuit board may also include ground planes, power planes, or other desired features. In some embodiments, the features of both the integrated system on module and the application-specific module are both formed simultaneously during operation 408. A common interface is formed on or within the circuit board, where the integrated system on module design and the application-specific module design interface. Testing may optionally be performed on the completed circuit board to ensure that the designs have been accurately incorporated into the completed circuit board. The process of building the circuit board can be accomplished manually, in a fully automated process, or in a combination of manual and automated processes.

After the circuit board has been built, the electrical components of the electronic product are populated on the circuit board in operation 410. In other words, the integrated system on module components and the application-specific module components are all installed, soldered, fastened, or otherwise connected to the appropriate locations on the completed circuit board, according to the designs of the electronic product.

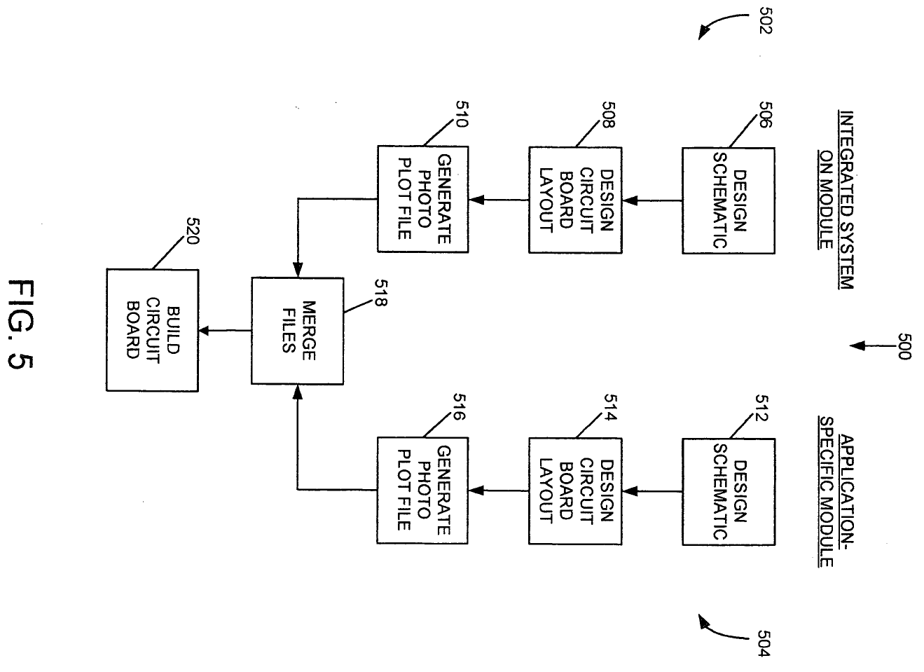

FIG. 5 is a flow chart illustrating an example method 500 of forming a circuit board, such as circuit board 102 shown in FIG. 1. Method 500 begins with two parallel processes 502 and 504. Process 502 includes operations 506, 508, and 510 that relate to the design of the integrated system on module. Process 504 includes operations 512, 514, and 516 that relate to the design of the application-specific module. These processes can be performed simultaneously, one after the other, or in any other desired order. In one possible embodiment, process 502 is performed independent of process 504. One way in which this can be done, is by defining a common interface at which the integrated system on module and the application-specific module will meet.

Process 502 begins with operation 506, during which the schematic is designed for the integrated system on module. Schematic design of electronic circuits is well known, and can be performed using various software tools if desired. One example is OrCAD® manufactured by Cadence™ Design Systems.

After the schematic design is complete, operation 508 is then performed to design the circuit board layout for the integrated system on module. In some embodiments, operation 508 involves defining the type and location of components on the circuit board, defining the size and location of traces on the circuit board, and defining other features of the circuit board, such as vias, holes, electrical contacts, antennas, ground planes, or any other desired features.

Once the circuit board layout design is complete, operation 510 is performed to generate a photo plot file for the integrated system on module. In some embodiments, the photo plot file is a gerber file. A gerber file is a standard file used by many printed circuit board (“PCB”) fabrication houses that contains information that is used, for example, to draw signal traces, land patterns, drill holes, mill, and cut the printed circuit board.

In the illustrated embodiment, process 504 is the same as process 502 except that it involves the design of the application-specific module, rather than the integrated system on module. Process 504 begins with operation 512 to design the schematic diagram for the application-specific module. Next, operation 514 is performed to design the circuit board layout based on the schematic diagram. Operation 516 is then performed to generate the photo plot file, such as a gerber file.

Once processes 502 and 504 have both been completed, operation 518 is then performed to merge the design of the integrated system on module with the design of the application-specific module. In operation 514, the photo plot files are merged together, such as to generate a single photo plot file for the electronic product. In a possible embodiment, operation 518 is performed by importing the integrated system on module photo plot file into the application-specific module photo plot file. In another possible embodiment, operation 518 is performed by importing the application-specific module photo plot file into the integrated system on module photo plot file.

In some embodiments in which photo plot files (generated in operations 510 and 516) are designed to incorporate multiple layers, the photo plot files include separate sets of data for each of the layers. Operation 518 involves merging data from one layer of one file individually with the corresponding layer of the other file. For example, the first layer of the integrated system on module design is merged with the first layer of the application-specific module design. The process is repeated for each layer until all layers of both photo plot files have been merged.

A printed circuit board is built in operation 520, following the merger of the designs in operation 518. Building of the circuit board involves forming the desired features on a circuit board based on the merged photo plot file. After the board has been built, it may then be populated with the desired components.

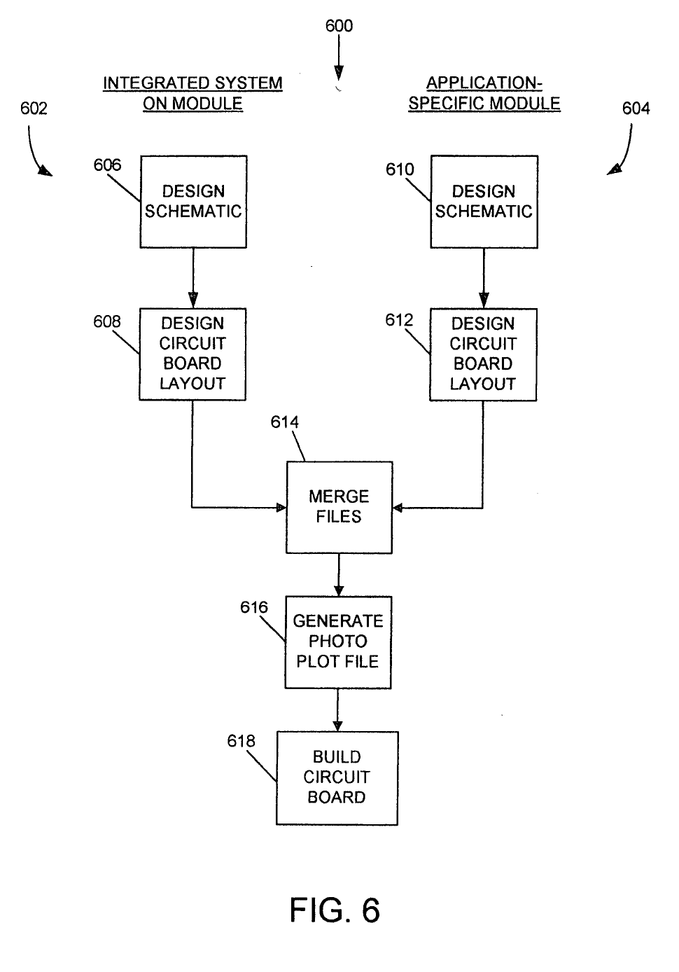

FIG. 6 is a flow chart illustrating another example method 600 of forming a circuit board, such as circuit board 102 shown in FIG. 1. Method 600 includes process 602 and process 604. In one embodiment, process 602 is performed simultaneously with process 604. In another embodiment, one of processes 602 or 604 is performed before the other process. Process 602 involves the design of the integrated system on module, such as integrated system on module 104 shown in FIG. 1. Process 604 involves the design of the application-specific module, such as application-specific module 106 shown in FIG. 1. Processes 602 and 604 begin with operations 606 and 608 respectively, during which the schematics of each module are designed. Following the schematic design, operations 608 and 610 are performed, during which the circuit board layout is designed for each module. In some embodiments, the schematic is designed manually such as by a user using a CAD software application. In some other embodiments, the schematic is generated from another computer aided design tool such as a silicon compiler program using a hardware description language (“HDL”) such as VHDL or Verilog. In still other embodiments, the schematic is designed using a combination of manual CAD design and automated design using a silicon compiler.

Operation 614 is performed following operations 608 and 612 to merge the integrated system on module layout with the application-specific module layout. In one embodiment, the integrated system on module layout is imported into the application-specific module layout. In another embodiment, the application-specific module layout is imported into the integrated system on module layout. In this way, a single circuit board layout is generated for the electronic product.

In some embodiments in which the board layout designs (generated in operations 08 and 612) include multiple layers, the circuit board layout designs include separate sets of data for each of the layers. Operation 614 involves merging data from one layer of one file individually with the corresponding layer of the other file. For example, the first layer of the integrated system on module design is merged with the first layer of the application-specific module design. The process is repeated for each layer until all layers of both circuit board layout files have been merged.

Operation 616 is then performed to generate the photo plot file from the merged circuit board layout designs. A circuit board is then built in operation 618, after which the circuit board is populated with electronic components.

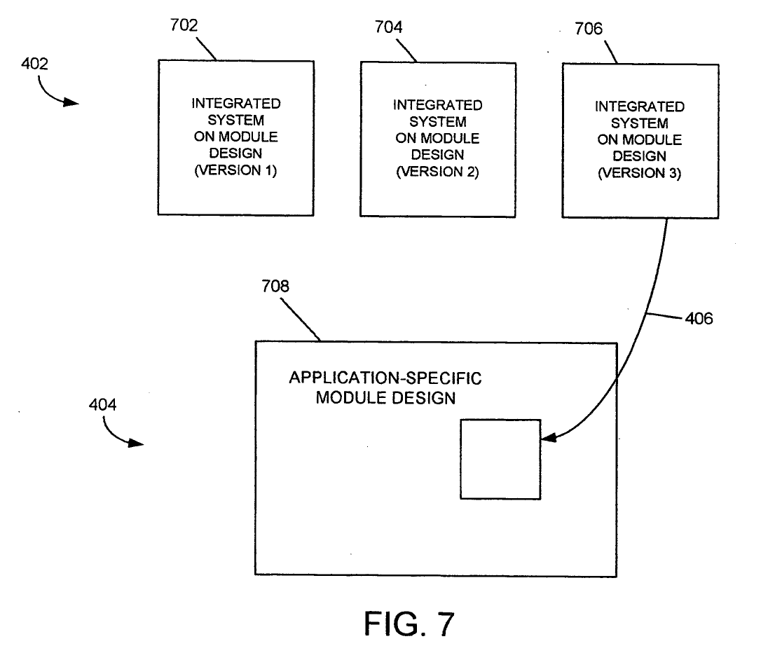

FIG. 7 is a block diagram further illustrating an example of operations 402, 404, and 406. In operations 402, 404, and 406, an integrated system on module design and an application-specific module design, are designed and merged, such as shown in FIG. 4. Operation 402 involves designing an integrated system on module. In the illustrated embodiment, three different versions of the integrated system on module are designed, including version 1 (702), version 2 (704), and version 3 (706).

In one embodiment, version 1 (702) is a basic design having only a basic set of features and components. Version 2 (704) is a design having more features or components than version 1 (702). Version 3 (706) is the premium design, such as having more features or components than the other versions.

In another embodiment, the versions represent advancements or improvements that have been made to the integrated system on module over time. For example, version 1 (702) represents the first version that was designed. Over time it is realized that various improvements can be made, and therefore version 2 (704) is designed. Version 2 (704) has improvements over version 1, such as a faster processor, improved software or firmware, or other desired improvements. After version 2 (704) is designed, however, it is again realized that further improvements can be made, and therefore version 3 (706) is designed including those improvements. In other embodiments, versions are not necessarily improvements over previous versions, but rather have different features or functions than the other versions, such that one version might be better suited to a particular application than another version. In another embodiment, a new version could replace an earlier version that could no longer be built because some of the components used in the earlier version have become obsolete or unobtainable.

When it comes time to build an electronic product, the product developer can select between the various versions of the integrated system on module design. In the illustrated example, the product developer can select from among the three available versions (702, 704, or 706). Each version is designed to have the same common interface, and therefore each version is interchangeable with the other versions. In this example, the product developer chooses version 3 (706). Operation 406 is then performed to merge version 3 of the integrated system on module design (706) with application-specific module design 708.

In some embodiments multiple benefits are realized by this method. One of the benefits is that changes, modifications, or upgrades can be made to the integrated system on module design without requiring that any changes be made to the application-specific module design. Similarly, changes can also be made to the application-specific module design without requiring that any changes be made to the integrated system on module design. For example, if after designing versions 1 (702) and 2 (704) of the integrated system on module it was realized that additional improvements could be made, version 3 (706) of the integrated system on module could be subsequently designed. So long as the common interface remains unchanged in the upgrade to version 3, no changes are required to the application-specific module design. In this case, the resulting electronic product is designed by merging version 3 (706) of the integrated system on module design with the previously designed application-specific module design. Another benefit realized by some embodiments is that the time and resources required to make upgrades or design modifications is reduced, because the entire electronic product does not need to be redesigned when changes are desired.

In addition to the ability to have multiple versions of the integrated system on module design, it is also possible to have multiple versions of the application-specific module design. One of the benefits of this is that changes can made to an application-specific module design without requiring that any changes be made to the integrated system on module design. The product developer may select which integrated system on module design to use in an electronic product, and also select which application-specific module design should be used in the electronic product. Once the selection has been made, the selected designs are then merged to generate a complete design for the desired electronic product.

The various embodiments described above are provided by way of illustration only and should not be construed to limit the claims attached hereto. Those skilled in the art will readily recognize various modifications and changes that may be made without following the example embodiments and applications illustrated and described herein, and without departing from the true spirit and scope of the following claims.

What is claimed is:

1. An electronic product comprising:
a circuit board;
an integrated system on module comprising a plurality of integrated system on module components arranged within a bounded region of the circuit board, the integrated system on module components being further arranged to perform a desired system function;
an application-specific module comprising a plurality of application-specific module components arranged outside of the bounded region of the circuit board, the application-specific module components further arranged to perform an application-specific function; and
a common interface proximate to the bounded region, wherein the integrated system on module and the application-specific module are electrically coupled at the common interface, and wherein the integrated system on module and the application-specific module are integrated with the circuit board.

2. The electronic product of claim 1, wherein the common interface is selected from the group comprising a plurality of vias in the circuit board; a set of pad locations, and a set of trace termination locations.

3. The electronic product of claim 2, wherein the common interface at least partially surrounds the bounded region.

4. The electronic product of claim 1, the integrated system on module components comprising a processing device, memory readable by the processing device, and a communication system arranged to enable communication with the processing device.

5. The electronic product of claim 4, wherein the processing device is selected from the group comprising: a central processing unit, a microcontroller, a programmable logic device, a field programmable gate array, a digital signal processing device, a reduced instruction set computing device, a complex instruction set computing device, and an application-specific integrated circuit device.

6. The electronic product of claim 1 wherein the integrated system on module components are selected from the group comprising: a processing device, an audio CODEC, a touch screen controller, a power supply, a network controller, a complex programmable logic device, flash memory, a buffer, and synchronous dynamic access memory.

7. The electronic product of claim 1, wherein the application-specific module components are selected from the group comprising: a network communication connector, a serial port connector, an audio connector, a touch screen connector, a display connector, a memory slot, a power input jack, a power regulator, and an input button.

8. A method of generating a circuit board layout:
defining a common interface between an integrated system on module and an application-specific module, the common interface being proximate to an edge of a bounded region;
defining a first layout of the integrated system on module including a plurality of integrated system on module components within the bounded region;
defining a second layout of the application-specific module including a plurality of application-specific module components outside of the bounded region;
and
merging the first layout with the second layout at the common interface to generate a circuit board layout that includes the first layout and the second layout and defines an electrical coupling between the integrated system on module and the application-specific module at the common interface.

9. The method of claim 8, wherein defining the common interface comprises one of defining a plurality of via locations, defining a plurality of contact points, defining a plurality of pads, and defining a plurality of trace termination locations.

10. The method of claim 9, wherein the common interface at least partially surrounds the bounded region.

11. The method of claim 8, wherein the first layout and the second layout are one of a photo plot file and a circuit board layout file.

12. The method of claim 8, further comprising constructing a single circuit board based on the circuit board layout.

13. The method of claim 12, further comprising populating the circuit board with the plurality of integrated system on module components and with the plurality of application-specific module components.

14. A method of generating a layout for an integrated system on module:
defining a common interface for electrically coupling the integrated system on module and an application-specific module on a single circuit board, wherein the common interface is proximate to an edge of a region of space; and
defining a layout for an integrated system on module within the region of space and conforming to the common interface, the integrated system on module comprising a plurality of components arranged to perform a system function and to communicate with an application-specific module.

15. The method of claim 14, wherein the region of space is the footprint of the integrated system on module.

16. The method of claim 14, wherein defining the layout for the integrated system on module is performed by a process selected from the group comprising: a fully automated process, a fully manual process, and a process which is partially automated and partially manual.

17. A method of forming a layout for an electronic product:
defining a common interface proximate to an edge of a bounded region;
defining a first layout for a first integrated system on module including a first plurality of components, wherein the first layout conforms to the common interface and fits within the bounded region;
defining a second layout for a second integrated system on module including a second plurality of components, wherein the second layout conforms to the common interface and fits within the bounded region;
defining a third layout for an application-specific module including a third plurality of components, wherein the third layout conforms to the common interface and is arranged to be outside of the bounded region;
selecting from among the first layout and the second layout; and
merging the selected layout with the third layout to define a fourth layout for an electronic product including an electrical coupling between the selected layout and the third layout at the common interface, wherein the fourth layout is arranged to be constructed on a single circuit board.

18. The method of claim 17, wherein defining the common interface comprises:
identifying a footprint of the first integrated system which defines the bounded region; and
defining a plurality of trace termination locations in close proximity to the edges of the footpoint.

19. A method of forming a layout for an electronic product:
defining a common interface proximate to an edge of a bounded region;
defining a first layout for a first integrated system on module including a first plurality of components, wherein the first layout conforms to the common interface and fits within the bounded region;
defining a second layout for a first application-specific module including a second plurality of components, wherein the second layout conforms to the common interface and is arranged to be outside of the bounded region;
defining a third layout for a second application-specific module including a third plurality of components, wherein the third layout conforms to the common interface and is arranged to be outside of the bounded region;
selecting from among the second layout and the third layout; and
merging the first layout with the selected layout to define a fourth layout for an electronic product including an electrical coupling between the selected layout and the third layout at the common interface, wherein the fourth layout is arranged to be constructed on a single circuit board.

20. The method of claim 19, wherein merging the first layout with the selected layout is performed by a process selected from the group comprising: a fully automated process, a fully manual process, and a process which is partially automated and partially manual.
